(19) United States
(12) Patent Application Publication
(10) Pub. No.: US 2017/0177259 A1
(43) Pub. Date: Jun. 22, 2017

(54) Techniques to Use Open Bit Line Information for a Memory System

(71) Applicant: Intel Corporation, Santa Clara, CA (US)

(72) Inventor: RAVI H. MOTWANI, SAN DIEGO, CA (US)

(73) Assignee: Intel Corporation, Santa Clara, CA (US)

(21) Appl. No.: 14/975,543

(22) Filed: Dec. 18, 2015

(51) Int. Cl. G06F 3/06; H03M 13/29; G06F 11/10

(52) U.S. Cl. CPC G06F 3/0631; G06F 3/0604; G06F 3/0644; G06F 3/0673; G06F 11/1076; H03M 13/2906

(57) ABSTRACT

Examples are given for techniques to use open bit line information for a memory system. In some examples, open information indicating locations of open bit lines for physical memory addresses of one or more memory devices may be used to successfully decoded ECC encoded data stored to the one or more memory devices. The open information, in some instances, is stored with the ECC encoded data and is available for use to enable a successful correction of errors in the ECC encoded data following a read request that causes the ECC encoded data to be read from the physical memory addresses.

### RELATED CASE

This application is related to commonly owned U.S. patent application Ser. No. 14/671,140 filed on Mar. 3, 2015, entitled “Apparatus and Method for Detecting and Mitigating Bit-Line Opens in Flash Memory”.

### TECHNICAL FIELD

Examples described herein are generally related to techniques for error correction coding.

### BACKGROUND

Defects in the form of open lines or shorts may occur in memory systems including one or more memory devices or dies. In some instances, open lines in memory systems including non-volatile types of memory devices or dies such as NAND flash memories may be more prevalent than other types of memory. These defects may be present at a time of manufacture, may appear through an operating life of a memory device or may appear due to operating conditions such as environmental temperature extremes. Defects such as open lines or shorts may negatively contribute to a performance of a memory device that is often measured by a raw bit error rate (RBER). RBER refers to a rate of bit errors when reading data that has been stored in memory device and open lines increase RBERs for most if not all memory devices.

### BRIEF DESCRIPTION OF THE DRAWINGS

FIG. 1 illustrates an example first system.

FIG. 2 illustrates an example open identification scheme.

FIG. 3 illustrates an example second system.

FIG. 4 illustrates an example apparatus.

FIG. 5 illustrates an example logic flow.

FIG. 6 illustrates an example storage medium.

FIG. 7 illustrates an example storage device.

FIG. 8 illustrates an example computing platform.

### DETAILED DESCRIPTION

As contemplated in the present disclosure, defects such as open lines or shorts may increase an RBER for a memory device. If an error correction code (ECC) such as low-density parity-check (LDPC) is used to encode data prior to storing to the memory device, then when a soft read operation is performed to read the data from the memory device, open lines or shorts may manifest as errors with high confidence (e.g., errors having a high reliability value, where reliability is the magnitude of the log likelihood ratio (LLR)). Each open line or short may be associated with a separate bit line and is hereafter referred to as an open bit line.

A first problem with an open bit line for a memory device is that a memory cell for the open bit line may not be used to store data. A second problem with the open bit line is that high confidence errors are typically more detrimental to an ECC's ability to correct as compared to correcting soft errors. For example, use of an ECC such as LDPC may allow for decoding to continue for soft errors while high confidence or hard errors may cause LDPC to fail.

Techniques have been developed to locate open bit lines in a memory system or device via a special read command during read operations. These techniques, following location of the open bit lines, may include identifying the open bits lines as erasures. The ECC code may then more effectively handle data read from physical memory addresses knowing that these open bit lines are erasures. However, the special read command may unacceptably affect memory throughputs. Also, for some types of non-volatile memory such as three-dimensional (3-D) cross-point memory or stacked NAND memory, high opens probabilities may occur and consequently the number of special reads to address open bit lines may increase. Therefore, a need may exist to identify open bit lines without having to conduct special reads during most if not all read operations.

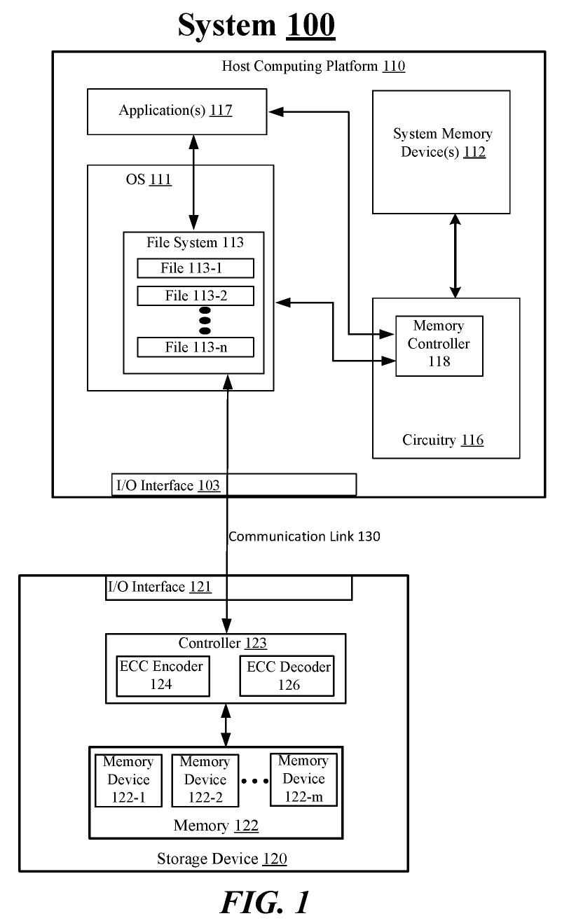

FIG. 1 illustrates an example system 100. In some examples, as shown in FIG. 1, system 100 includes a host computing platform 110 coupled to a storage device 120 through input/output (I/O) interface 103 and I/O interface 123. Also, as shown in FIG. 1, host computing platform 110 may include an OS 111, one or more system memory device(s) 112, circuitry 116 and one or more application(s) 117. For these examples, circuitry 116 may be capable of executing various functional elements of host computing platform 110 such as OS 111 and application(s) 117 that may be maintained, at least in part, within system memory device(s) 112. Circuitry 116 may include host processing circuitry to include one or more central processing units (CPUs) and associated chipsets and/or controllers.

According to some examples, as shown in FIG. 1, OS 111 may include a file system 113 to coordinate storage of data received from application(s) 117 in a file from among files 113-1 to 113-n, where “n” is any whole positive integer >1, to storage in a memory 122 at storage device 120. The data, for example, may have originated from or may be associated with executing at least portions of application(s) 117 and/or OS 111. The data may be a chunk of data that has been source encoded. For example, source encoded by file system 113 or source encoded by application(s) 117. As described in more detail below, the source encoded chunk of data may be compressed enough to allow for open information indicating locations of open bit lines to be appended or encoded with the chunk of data upon storage in memory 122.

As shown in FIG. 1, storage device 120 includes a controller 123 coupled with memory 122. According to some examples, controller 123 may receive and/or fulfill read/write requests via communication link 130 through I/O interface 121. Storage device 120 may be a memory device for host computing platform 110. As a memory device, storage device 120 may serve as a solid state drive (SSD) for host computing platform 110.

In some examples, as shown in FIG. 1, controller 123 may include an error correction code (ECC) encoder 124 and an ECC decoder 126. ECC encoder 124 may include logic and/or features to generate codewords to protect chunks of data to be written to memory 122 that may or may not include open information indicating locations of open bit lines for physical memory addresses of memory devices included in memory 122. As described in more detail below, ECC decoder 126 may include logic and/or features to detect, locate, possibly evaluate and correct errors included in an ECC encoded chunk of data and in the event of a failure to correct bit errors may utilize open information (e.g., as erasures) in order to successfully correct the bit errors. According to some examples, the ECC used to encode the data may include, but is not limited to, an LDPC code, a Reed-Solomon (RS) code or a Bose, Chaudhuri, and Hocquenghem (BCH) code.

In some examples, as shown in FIG. 1, memory 122 may include memory devices 122-1 to 122-m, where “m” is any positive whole integer >1. For these examples, memory devices 122-1 to 122-m may include non-volatile and/or volatile types of memory. Non-volatile types of memory may be types of memory whose state is determinate even if power is interrupted to the device. In some examples, memory devices 122-1 to 122-m may be block addressable memory devices, such as NAND or NOR technologies. Memory devices 122-1 to 122-m may also include future generations of non-volatile types of memory, such as a 3-D cross-point memory, or other byte addressable non-volatile memory. Memory devices 122-1 to 122-m may include memory devices that use chalcogenide phase change material (e.g., chalcogenide glass), multi-threshold level NAND flash memory, NOR flash memory, single or multi-level phase change memory (PCM), a resistive memory, nanowire memory, ferroelectric transistor random access memory (FeTRAM), magnetoresistive random access memory (MRAM) memory that incorporates memristor technology, or spin transfer torque MRAM (STT-MRAM), or a combination of any of the above, or other memory types.

According to some examples, volatile types of memory included in memory devices 122-1 to 122-m and/or included in system memory device(s) 112 may include, but are not limited to, random-access memory (RAM), Dynamic RAM (D-RAM), double data rate synchronous dynamic RAM (DDR SDRAM), static random-access memory (SRAM), thyristor RAM (T-RAM) or zero-capacitor RAM (Z-RAM). Memory devices including volatile types of memory may be compatible with a number of memory technologies, such as DDR4 (DDR version 4, initial specification published in September 2012 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (LPDDR version 5, currently in discussion by JEDEC), HBM2 (HBM version 2, currently in discussion by JEDEC), and/or others, and technologies based on derivatives or extensions of such specifications.

In some examples, communications between file system 113 and controller 123 for writing or reading of chunks of data stored in memory devices(s) 122 may be routed through I/O interface 103 and I/O interface 123. The I/O interfaces 103 and 123 may be arranged as a Serial Advanced Technology Attachment (SATA) interface to couple elements of host computing platform 110 to storage device 120. In another example, the I/O interfaces 103 and 123 may be arranged as a Serial Attached Small Computer System Interface (SCSI) (or simply SAS) interface to couple elements of host computing platform 110 to storage device 120. In another example, the I/O interfaces 103 and 123 may be arranged as a Peripheral Component Interconnect Express (PCIe) interface to couple elements of host computing platform 110 to storage device 120. In another example, I/O interfaces 103 and 123 may be arranged as a Non-Volatile Memory Express (NVMe) interface to couple elements of host computing platform 110 to storage device 120. For this other example, communication protocols may be utilized to communicate through I/O interfaces 103 and 123 as described in industry standards or specifications (including progenies or variants) such as the Peripheral Component Interconnect (PCI) Express Base Specification, revision 3.1, published in November 2014 (“PCI Express specification” or “PCIe specification”) and/or the Non-Volatile Memory Express (NVMe) Specification, revision 1.2, also published in November 2014 (“NVMe specification”).

In some examples, system memory device(s) 112 may store information and commands which may be used by circuitry 116 for processing information. Also, as shown in FIG. 1, circuitry 116 may include a memory controller 118. Memory controller 118 may be arranged to control access to data at least temporarily stored at system memory device(s) 112 for eventual storage to storage memory device(s) 122 at storage device 120.

According to some examples, host computing platform 110 may include, but is not limited to, a server, a server array or server farm, a web server, a network server, an Internet server, a work station, a mini-computer, a main frame computer, a supercomputer, a network appliance, a web appliance, a distributed computing system, multiprocessor systems, processor-based systems, or combination thereof.

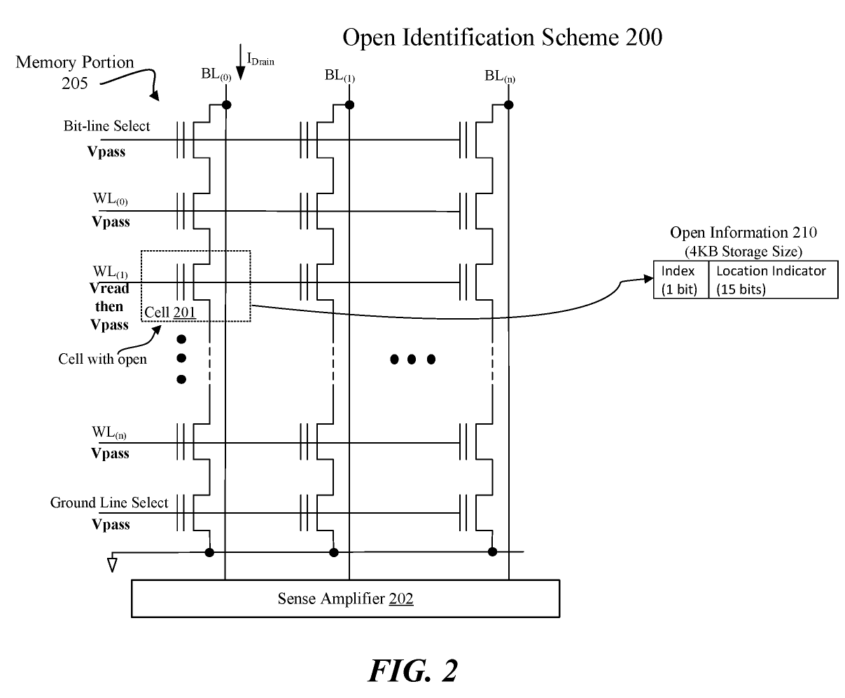

FIG. 2 illustrates an example open identification scheme 200. In some examples, as shown in FIG. 2, open identification scheme 200 is for a memory portion 205 that may be part of a NAND type of memory. Memory portion 205, as shown in FIG. 2, may include strings of floating gate transistors (or cells), such that the transistors are coupled in series. A gate terminal of a first transistor in each string may be coupled to a bit line (e.g., BL₍₀₋₍ₙ₎) and controllable by a bit line select signal. A last transistor in each string may be coupled to ground (or a source line) and controllable by a source line select signal (or ground select signal). Remaining transistors in the string may be coupled to word lines (e.g., WL₍₀₎₋₍ₙ₎).

According to some examples, in an absence of defects, to read a value from a memory cell in a string, the bit line select and ground select signals may be asserted and one of the BLs may be selected (e.g., BL₍₀₎). For these examples, to select a memory cell of interest in the enabled or selected string, a WL for that cell may be set to a read voltage (Vread) and the remaining WLs may be set to a pass voltage (Vpass). The pass voltage may be the voltage which is high enough to allow the memory cell to pass its value down to ground, while the read voltage is the threshold voltage for the memory cell. Depending on a charge stored in the memory cell of interest and the read voltage, the BL is discharged or retains a certain charge. The BL is then sensed by sense amplifier 202 and the stored value (or state) in the selected memory cell is determined.

In some examples, in a case of a defect, such as an open circuit in one of the memory cells of the selected string, a BL is not discharged to ground. For example, memory cell 201 may have an open circuit (e.g., an open bit line). This open bit line may generate soft errors with high confidence during ECC decoding (e.g., LDPC decoding).

According to some examples, the location of the open bit line for memory cell 201 may be identified responsive to a command to perform a special read operation that includes applying Vpass to all WLs of memory portion 205. By applying Vpass for the special read operation, the location of the open bit line may be determined.

According to some examples, memory portion 205 may be part of physical memory addresses arranged to store a chunk of data of a given storage size of 4 kilobytes (KB). For these examples, open information 210 may include a 1 bit index and a 15 bit location indicator. Open information for other memory cells included in the physical memory addresses may include a similar format of the 1 bit index and a 15 bit location indicator.

In some examples, opens probability associated with the memory for which memory portion 205 is part of may be 3e-3 and thus up to 115 open circuits or open bit lines may occur with a probability of 0.956 for this memory. Thus, in order to store the open information to indicate open bit lines for these 115 open circuits, 16 bits×115 or 1840 bits of storage is needed. Also, if the open information is ECC protected with a rate of 0.9 BCH code, an additional 184 bits are needed. That brings the total storage needed for the ECC encoded open information to 2024 bits. As described more below, ECC encoder 124 may receive a chuck of data that has been source encoded such that the data may or may not have been compressed enough to allow for open information to be stored with the chunk of data following the encoding of the chunk of data. For those instances were insufficient compression has occurred for joint storage, open information may be obtained at the time that the encoded chunk of data is decoded.

According to some examples, the physical memory addresses arranged to store the chunk of data may be for a memory band. For these examples, open information such as open information 210 may be for physical memory addresses arranged to store the chunk of data of a given storage size (e.g., 4 KB) to the memory band. The memory band, for example, may include an assigned storage space accessible to logic and/or features of a controller for the memory (e.g., controller 123) to at least temporarily store the open information for possible storage with chunks of data received from a host computing platform (e.g., from application(s) 117 and/or file system 113).

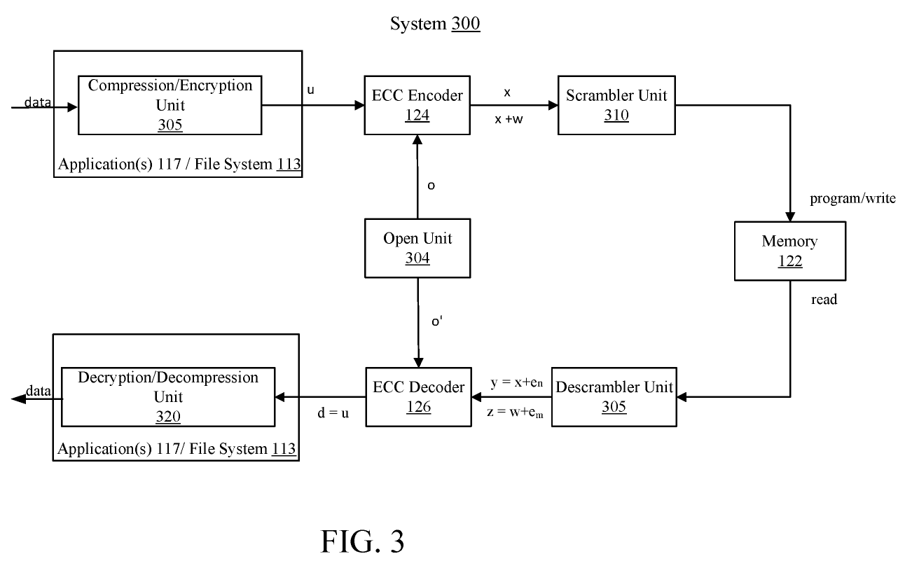

FIG. 3 illustrates an example system 300. In some examples, as shown in FIG. 3, system 300 includes a compression/encryption unit 305 that may be implemented by application(s) 117 and/or file system 113. System 300 in also shown as including ECC encoder 124, a scrambler unit 310, memory 122, a descrambler unit 305, ECC decoder 126 and a decryption/decompression unit 320 that may also be implemented by application(s) 117 and/or file system 113.

According to some examples, as shown in FIG. 3, compression/encryption of data at compression/encryption unit 305 may result in “u”. In some examples, u may represent a chunk of data that may be source encoded using various compression schemes or algorithms. For example, application(s) 117 and/or file system 113 may be part of a Linux-based file system that uses Btrfs compression. In other examples, application(s) 117 and/or file system 113 may implemented as part of an open-source database system such as MySQL that may use an InnoDB engine to compress data. In other examples, application(s) 117 and/or file system 113 may be part of an open-source file system such as ZFS that may compress the chunk of data represented by u into a given block size. In other examples, application(s) 117 and/or file system 113 may be part of a proprietary-based Windows® file system that may use a compression scheme similar to ZFS. Examples, are not limited to the above mentioned examples of source encoding that may result in compression of the chunk of data represented by u in FIG. 3.

According to some examples, ECC encoder 124 may receive u and generate a codeword “x” using ECC (e.g., LDPC, BCH or RS). ECC encoder 124 may also include logic and/or features to obtain or receive open information from an open unit 304 (e.g., part of controller 123's logic and/or features) that indicates locations of open bit lines “o” for physical memory addresses of one or more memory devices included in memory 122 that are arranged to store an encoded chunk of data of a given storage size. For example, the given storage size may be a storage size of 4 KB. Open locations o may be identified responsive to a special read command (e.g., Vpass read command—see FIG. 2) to the physical memory addresses. Open unit 304 may be capable of at least temporarily maintaining o during write operations (e.g., in a memory accessible to controller 123 or open unit 304) to the physical memory addresses.

In some examples, ECC encoder 124 may also include logic and/or features to determine whether a combined storage size of x and a storage size of o that may also be ECC encoded to generate a separate codeword “w” exceeds the given storage size for the physical memory addresses of the one or more memory devices included in memory 122. In other words, ECC encoder 124 determines whether x+w exceeds the given storage size (e.g., 4 KB). As mentioned above, the chunk of data u received from application(s) 117/file system 113 may have been compressed such that even after being ECC encoded to generate x, the storage size needed to store x still leaves room in the physical memory addresses to also store w. If ECC encoder 124 determines that x and w do not exceed the given storage size, then x+w may be stored in memory 122. Storing w with x, may eliminate a need to perform a special read to identify open bit lines during decoding of x. If x and w are determined to exceed the given storage size then only x is stored in memory 122.

Scrambler unit 310 may receive x or x+w and cause x or x+w to be programmed or written to memory 122. The codeword(s) may be read from memory devices 122-1 to 122-m of memory 122 and descrambled by descrambler unit 305 to result in a codeword “y” and/or “z”. As shown in FIG. 3, y=x+eₙ, and z=w+eₘ where “eₙ” and “eₘ” respectively represent errors possibly introduced during the writing then reading of x and w from memory devices 122-1 to 122-m of memory 122 and “n” or “m” represents the number of errors introduced during the writes and reads from memory devices 122-1 to 122-m of memory 122.

In some examples where w was stored with x, ECC decoder 126 may receive y and z. For these examples, ECC decoder 126 may include logic and/or features to first attempt to correct identified errors to generate “d”. If the errors were correctable, d=u and then ECC decoder 126 may discard z due to this successful correction of the errors. However, if ECC decoder 126 is not successful, ECC decoder 126 may decode z, correct any errors included in z (if any) and then obtain the open information to identify locations of open bit lines for the physical memory addresses of memory 122 that were read from memory 122 to obtain y and z. ECC decoder 126 may then re-attempt to correct the errors in y using the identified locations of open bit lines as erasure. If the errors were correctable using the identified locations of open bit lines as erasure, d=u.

According to some examples where open information was not stored with x to memory 122, ECC decoder 126 may only receive y from descrambler unit 305. For these examples, ECC decoder 126 may first attempt to correct identified errors to generate d. If the errors were correctable, d=u. However, if ECC decoder 126 is not successful, ECC decoder 126 may cause or request that open unit 304 issue a special read command (e.g., Vpass read command) to identify locations of open bit lines for the physical memory addresses of memory 122 that were read from memory 122 to obtain y. Open unit 304 may provide those identified locations as “o′” to ECC decoder 126 and ECC decoder 126 may then re-attempt to correct the errors in y using the identified locations of open bit lines as erasures. If the errors were correctable using the identified locations of open bit lines as erasures, d=u. As mentioned previously, having to obtain locations of open bit lines may add latency due to the extra read command that is needed compared to already having that information (e.g., having z) when decoding y.

Decryption/Decompression unit 320 may then decrypt/decompress u to generate data originally compressed/encrypted by compression/encryption unit 305 included in application(s) 117 and/or file system 113.

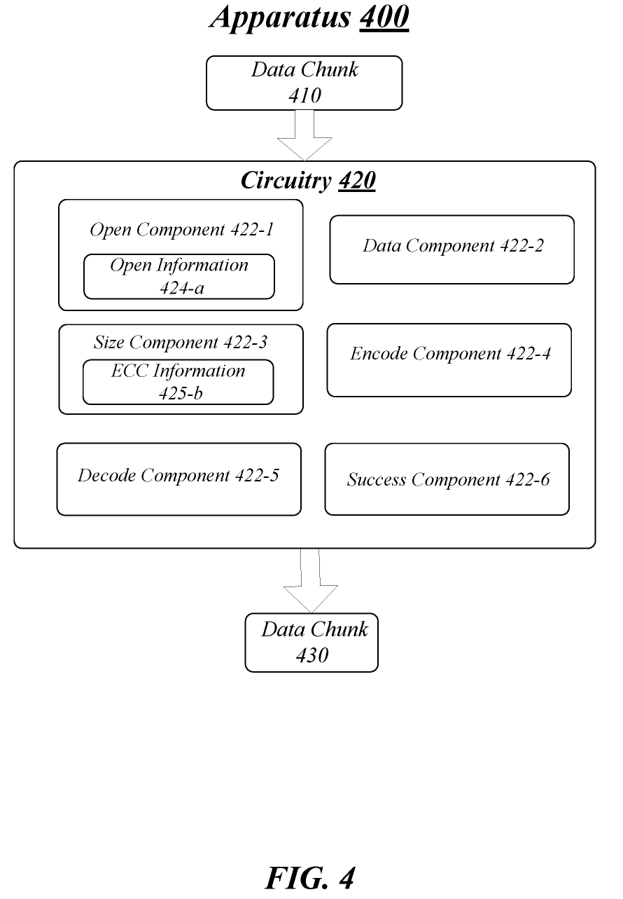

FIG. 4 illustrates an example apparatus 400. Although the apparatus 400 shown in FIG. 4 has a limited number of elements in a certain topology, it may be appreciated that the apparatus 400 may include more or less elements in alternate topologies as desired for a given implementation.

The apparatus 400 may be supported by circuitry 420 that may execute at least some of the logic and/or features mentioned above for an ECC encoder such as ECC encoder 124 or for an ECC decoder such as ECC decoder 126 mentioned above for at least FIGS. 1 and 3. Circuitry 420 may be arranged to execute one or more software or firmware implemented components 422-a. It is worthy to note that “a” and “b” and “c” and similar designators as used herein are intended to be variables representing any positive integer. Thus, for example, if an implementation sets a value for a=6, then a complete set of software or firmware components 422-a may include components 422-1, 422-2, 422-3, 422-4, 422-5 or 422-6. The examples presented are not limited in this context and the different variables used throughout may represent the same or different integer values.

According to some examples, apparatus 400 may be capable of being located with a controller for a memory system, e.g., as part of a storage device such as storage device 120. For these examples, apparatus 400 may be included in or implemented by circuitry 420 to include a processor, processor circuitry, microcontroller circuitry, an application-specific integrated circuit (ASIC) or a field programmable gate array (FPGA). In other examples, apparatus 400 may be implemented by circuitry 420 as part of firmware (e.g., BIOS), or implemented by circuitry 420 as a middleware application. The examples are not limited in this context.

In some examples, if implemented in a processor, the processor may be generally arranged to execute one or more software modules 422-a. The processor can be any of various commercially available processors, including without limitation an AMD® Athlon®, Duron® and Opteron® processors; ARM® application, embedded and secure processors; IBM® and Motorola® DragonBall® and PowerPC® processors; IBM and Sony® Cell processors; Intel® Atom®, Celeron®, Core (2) Duo®, Core i3, Core i5, Core i7, Itanium®, Pentium®, Xeon®, Xeon Phi® and XScale® processors; and similar processors. Multi-core processors and other multi-processor architectures may also be employed to implement apparatus 400.

According to some examples, apparatus 400 may include an open component 422-1. Open component 422-1 may be logic and/or features executed by circuitry 420 to receive open information indicating locations of open bit lines for physical memory addresses of one or more memory devices maintained at a memory system, the physical memory addresses arranged to store a chunk of data of a given storage size. For these examples, open component 422-1 may maintain the received open information with open information 425-a (e.g., in a lookup table (LUT)).

In some examples, apparatus 400 may also include a data component 422-2. Data component 422-2 may be logic and/or features executed by circuitry 420 to receive a first chunk of data for storage to the physical memory addresses. For these examples, the first chunk of data may be included in data chunk 410.

According to some examples, apparatus 400 may also include a size component 422-3. Size component 422-3 may be logic and/or features executed by circuitry 420 to determine whether the combined storage size of the first chunk of data and the open information exceeds the given storage size. For these examples size component 422-3 may maintain ECC information 425-b (e.g., in a data structure such as LUT) that includes information related to additional bits that may be added to the first chunk and the open information when encoded with an ECC such as LPDC, BCH or RS codes. This information may be used to determine whether the combined storage size exceeds the given storage size.

In some examples, apparatus 400 may also include an encode component 422-4. Encode component 422-4 may be logic and/or features executed by circuitry 420 to encode the first chunk of data using a first ECC. Encode component 422-2 may also encode the open information using a second ECC, if size component 422-3 has determined that the combined storage size does not exceed the given storage size. For these examples, the first and second ECC may be a same or different ECC.

According some examples, apparatus 400 may also include a decode component 422-5. Decode component 422-5 may be logic and/or features executed by circuitry 420 to decode the first ECC encoded first chunk of data responsive to receiving a read request for the first chunk of data stored to the physical memory addresses.

In some examples, apparatus 400 may also include a success component 422-6. Success component 422-6 may be logic and/or features executed by circuitry 420 to determine whether decode component 422-5 has successfully corrected detected errors in the first ECC encoded first chunk of data without using open information. For these examples, success component 422-6 may indicate to decode component 422-5 that the errors were unsuccessfully corrected. Decode component 422-5 may then decode the second ECC encoded open information and then use the identified locations of open bit lines as erasures. If this reattempted decoding of the first ECC encoded first chunk of data is deemed as successfully correcting errors by success component 422-6, the decoded first chunk of data may be included in data chunk 530 and sent to the source of the requestor of the read request.

According to examples where the open information was not encoded and stored with the first ECC encoded first chunk of data, decode component 422-5 may request that open component 422-1 obtain open information to identify locations of open bit lines for the physical memory addresses for which the first ECC encoded first chunk of data was stored. This request may occur if success component 422-6 determines that decode component 422-5 unsuccessfully corrected detected errors in the first ECC encoded first chunk of data without using open information. Decode component 422-5 may then use the identified locations of open bit lines as erasures. If this reattempted decoding of the first ECC encoded first chunk of data is deemed as successfully correcting errors by success component 422-6, the decoded first chunk of data may be included in data chunk 530 and sent to the source of the requestor of the read request.

Included herein is a set of logic flows representative of example methodologies for performing novel aspects of the disclosed architecture. While, for purposes of simplicity of explanation, the one or more methodologies shown herein are shown and described as a series of acts, those skilled in the art will understand and appreciate that the methodologies are not limited by the order of acts. Some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

A logic flow may be implemented in software, firmware, and/or hardware. In software and firmware embodiments, a logic flow may be implemented by computer executable instructions stored on at least one non-transitory computer readable medium or machine readable medium, such as an optical, magnetic or semiconductor storage. The embodiments are not limited in this context.

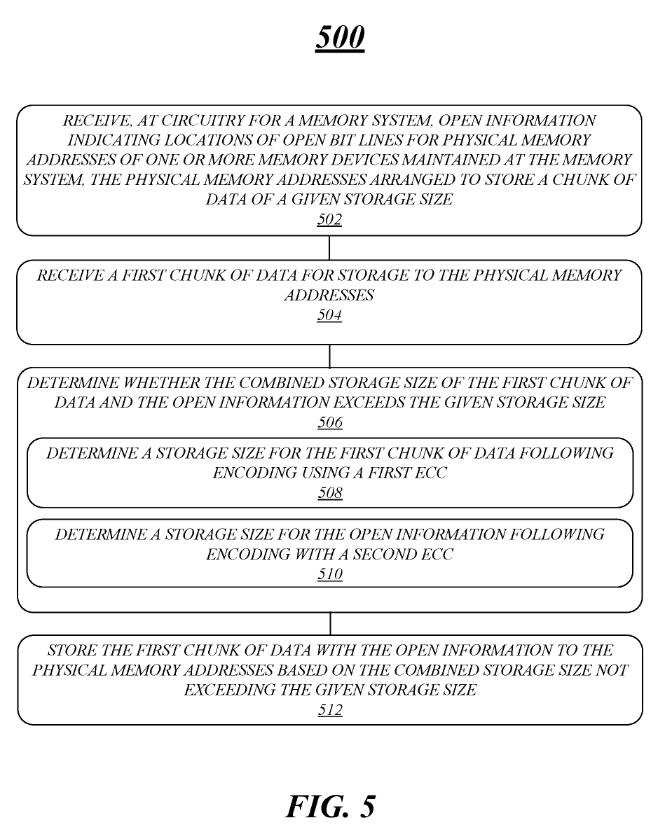

FIG. 5 illustrates a logic flow 500. Logic flow 500 may be representative of some or all of the operations executed by one or more logic, features, or devices described herein, such as apparatus 400. More particularly, logic flow 500 may be implemented by open component 422-1, data component 422-2, size component 422-3, encode component 422-4, decode component 422-5 or success component 422-6.

According to some examples, logic flow 500 at block 502 may receive, at circuitry for a memory system, open information indicating locations of open bit lines for physical memory addresses of one or more memory devices maintained at the memory system, the physical memory addresses arranged to store a chunk of data of a given storage size. For these examples, open component 422-1 may receive the open information.

In some examples, logic flow 500 at block 504 may receive a first chunk of data for storage to the physical memory addresses. For these examples, data component 422-2 may receive the first chunk of data (e.g., for a host computing device or platform).

According to some examples, logic flow 500 at block 506 may determine whether the combined storage size of the first chunk of data and the open information exceeds the given storage size. Size component 422-3 may determine whether the given storage size is exceeded. In some examples, to make this determination, logic flow 500 at block 508 may determine a storage size for the first chunk of data following encoding using a first ECC. Then logic flow 500 at block 510 may determine a storage size for the open information following encoding with a second ECC. For these examples, size component 422-3 uses both of these determination to determine whether the given storage size is exceeded.

In some examples, logic flow 500 at block 512 may store the first chunk of data with the open information to the physical memory addresses based on the combined storage size not exceeding the given storage size. For these examples, encode component 422-4 may encode the first chunk of data and the open information using first and second ECCs in order to store the first chunk of data with the open information to the physical memory addresses.

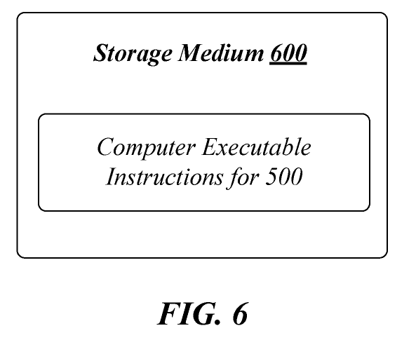

FIG. 6 illustrates an embodiment of a storage medium 600. The storage medium 600 may comprise an article of manufacture. In some examples, storage medium 600 may include any non-transitory computer readable medium or machine readable medium, such as an optical, magnetic or semiconductor storage. Storage medium 600 may store various types of computer executable instructions, such as instructions to implement logic flow 600. Examples of a computer readable or machine readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The examples are not limited in this context.

FIG. 7 illustrates an example storage device 700. In some examples, as shown in FIG. 7, storage device 700 may include a processing component 740, other storage device components 750 or a communications interface 760. According to some examples, storage device 700 may be capable of being coupled to a host computing device or platform.

According to some examples, processing component 740 may execute processing operations or logic for apparatus 400 and/or storage medium 600. Processing component 740 may include various hardware elements, software elements, or a combination of both. Examples of hardware elements may include devices, logic devices, components, processors, microprocessors, circuits, processor circuits, circuit elements (e.g., transistors, resistors, capacitors, inductors, and so forth), integrated circuits, ASIC, programmable logic devices (PLD), digital signal processors (DSP), FPGA/programmable logic, memory units, logic gates, registers, semiconductor device, chips, microchips, chip sets, and so forth. Examples of software elements may include software components, programs, applications, computer programs, application programs, device drivers, system programs, software development programs, machine programs, operating system software, middleware, firmware, software components, routines, subroutines, functions, methods, procedures, software interfaces, application program interfaces (API), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given example.

In some examples, other storage device components 750 may include common computing elements or circuitry, such as one or more processors, multi-core processors, co-processors, memory units, chipsets, controllers, interfaces, oscillators, timing devices, power supplies, and so forth. Examples of memory units may include without limitation various types of computer readable and/or machine readable storage media in the form of one or more higher speed memory units, such as read-only memory (ROM), RAM, DRAM, DDR DRAM, synchronous DRAM (SDRAM), DDR SDRAM, SRAM, programmable ROM (PROM), EPROM, EEPROM, flash memory, ferroelectric memory, SONOS memory, polymer memory such as ferroelectric polymer memory, nanowire, FeTRAM or FeRAM, ovonic memory, single or multi-level PCM, memristers, STT-MRAM, magnetic or optical cards, and any other type of storage media suitable for storing information.

In some examples, communications interface 760 may include logic and/or features to support a communication interface. For these examples, communications interface 760 may include one or more communication interfaces that operate according to various communication protocols or standards to communicate over direct or network communication links. Direct communications may occur via use of communication protocols such as SMBus, PCIe, NVMe, QPI, SATA, SAS or USB communication protocols. Network communications may occur via use of communication protocols Ethernet, Infiniband, SATA or SAS communication protocols.

Storage device 700 may be arranged as an SSD or an HDD that may be configured as described above for storage device 120 of system 100 as shown in FIG. 1. Accordingly, functions and/or specific configurations of storage device 700 described herein, may be included or omitted in various embodiments of storage device 700, as suitably desired.

The components and features of storage device 700 may be implemented using any combination of discrete circuitry, ASICs, logic gates and/or single chip architectures. Further, the features of storage device 700 may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It should be appreciated that the example storage device 700 shown in the block diagram of FIG. 7 may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

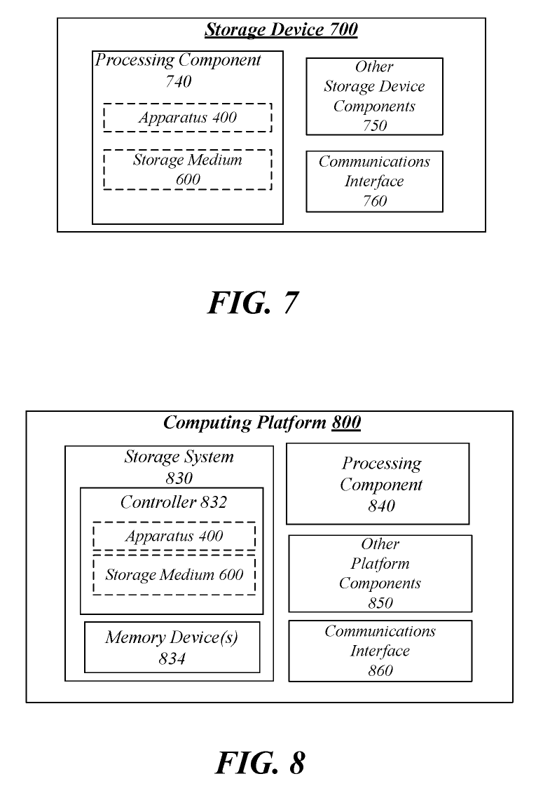

FIG. 8 illustrates an example computing platform 800. In some examples, as shown in FIG. 8, computing platform 800 may include a storage system 830, a processing component 840, other platform components 850 or a communications interface 860. According to some examples, computing platform 800 may be implemented in a computing device.

According to some examples, storage system 830 may be similar to storage device 120 of system 100 as shown in FIG. 1 and includes a controller 832 and memory devices(s) 834. For these examples, logic and/or features resident at or located at controller 832 may execute at least some processing operations or logic for apparatus 400 and may include storage media that includes storage medium 600. Also, memory device(s) 834 may include similar types of volatile or non-volatile memory (not shown) that are described above for storage device 120 shown in FIG. 1 or 3.

According to some examples, processing component 840 may include various hardware elements, software elements, or a combination of both. Examples of hardware elements may include devices, logic devices, components, processors, microprocessors, circuits, processor circuits, circuit elements (e.g., transistors, resistors, capacitors, inductors, and so forth), integrated circuits, ASIC, PLD, DSP, FPGA/programmable logic, memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given example.

In some examples, other platform components 850 may include common computing elements, such as one or more processors, multi-core processors, co-processors, memory units, chipsets, controllers, peripherals, interfaces, oscillators, timing devices, video cards, audio cards, multimedia I/O components (e.g., digital displays), power supplies, and so forth. Examples of memory units associated with either other platform components 850 or storage system 830 may include without limitation, various types of computer readable and machine readable storage media in the form of one or more higher speed memory units, such as ROM, RAM, DRAM, DDRAM, SDRAM, SRAM, PROM, EPROM, EEPROM, flash memory, ferroelectric memory, SONOS memory, polymer memory such as ferroelectric polymer memory, FeTRAM or FeRAM, ovonic memory, single or multi-level PCM, nanowire, memristers, STT-MRAM, magnetic or optical cards, an array of devices such as RAID drives, solid state memory devices, SSDs, HDDs or any other type of storage media suitable for storing information.

In some examples, communications interface 860 may include logic and/or features to support a communication interface. For these examples, communications interface 860 may include one or more communication interfaces that operate according to various communication protocols or standards to communicate over direct or network communication links. Direct communications may occur through a direct interface via use of communication protocols or standards described in one or more industry standards (including progenies and variants) such as those associated with the SMBus specification, the PCIe specification, the NVMe specification, the SATA specification, SAS specification or the USB specification. Network communications may occur through a network interface via use of communication protocols or standards such as those described in one or more Ethernet standards promulgated by the IEEE. For example, one such Ethernet standard may include IEEE 802.3-2012, Carrier sense Multiple access with Collision Detection (CSMA/CD) Access Method and Physical Layer Specifications, Published in December 2012 (hereinafter “IEEE 802.3”).

Computing platform 800 may be part of a computing device that may be, for example, user equipment, a computer, a personal computer (PC), a desktop computer, a laptop computer, a notebook computer, a netbook computer, a tablet, a smart phone, embedded electronics, a gaming console, a server, a server array or server farm, a web server, a network server, an Internet server, a work station, a mini-computer, a main frame computer, a supercomputer, a network appliance, a web appliance, a distributed computing system, multiprocessor systems, processor-based systems, or combination thereof. Accordingly, functions and/or specific configurations of computing platform 800 described herein, may be included or omitted in various embodiments of computing platform 800, as suitably desired.

The components and features of computing platform 800 may be implemented using any combination of discrete circuitry, ASICs, logic gates and/or single chip architectures. Further, the features of computing platform 800 may be implemented using microcontrollers, programmable logic arrays and/or microprocessors or any combination of the foregoing where suitably appropriate. It is noted that hardware, firmware and/or software elements may be collectively or individually referred to herein as “logic”, “circuit” or “circuitry.”

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations may be stored on a tangible, machine readable medium and supplied to various customers or manufacturing facilities to load into the fabrication machines that actually make the logic or processor.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may include an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The follow examples pertain to additional examples of technologies disclosed herein.

### Example 1

An example apparatus may include one or more memory devices. The apparatus may also include a controller that includes logic, at least a portion of which includes hardware. For these examples, the logic may receive open information indicating locations of open bit lines for physical memory addresses of the one or more memory devices. The physical memory addresses may be arranged to store a chunk of data of a given storage size. The logic may also receive a first chunk of data for storage to the physical memory addresses. The logic may also determine whether the combined storage size of the first chunk of data and the open information exceeds the given storage size. The logic may also cause the first chunk of data to be stored with the open information to the physical memory addresses based on the combined storage size not exceeding the given storage size.

### Example 2

The apparatus of example 1, the logic to determine whether the combined storage size of the first chunk of data and the open information exceeds the given storage size may the logic to determine a storage size for the first chunk of data following encoding using a first ECC and determine a storage size for the open information following encoding with a second ECC.

### Example 3

The apparatus of example 2, the logic may receive the first chunk of data from a host computing device. For these examples, the first chunk of data may be source encoded such that source data included in the first chunk of data has been compressed enough to enable the first chunk of encoded data and the open information to have the combined storage size that does not exceed the given storage size.

### Example 4

The apparatus of example 2, the first ECC and the second ECC may be a same ECC selected from one of an LDPC ECC, an RS ECC or a BCH ECC.

### Example 5

The apparatus of example 2, the first ECC and the second ECC may be different, the first ECC is an LDPC ECC and the second ECC is one of an RS ECC or a BCH ECC.

### Example 6

The apparatus of example 2, the logic to store the first chunk of data with the open information may include the logic to encode the first chunk of data using the first ECC. The logic may also encode the open information using the second ECC and cause the first ECC encoded first chunk of data to be stored with the second ECC encoded open information to the physical memory addresses.

### Example 7

The apparatus of example 6, the logic may receive a read request for the first chunk of data stored to the physical memory addresses. The logic may also decode the first ECC encoded first chunk of data. The logic, response to an unsuccessful correction of bit errors in the decoded first chunk of data using the first ECC, may also decode the second ECC encoded open information to identify locations of open bits lines for the physical memory addresses. The logic may also decode the first ECC encoded first chunk of data using the identified locations of open bit lines as erasures to successfully correct bits errors in the decoded first chunk of data using the first ECC.

### Example 8

The apparatus of example 2, the logic may receive a second chunk of data for storage to the physical memory addresses. The logic may also determine that the combined storage size of the second chunk of data and the open information exceeds the given storage size. The logic may also encode the chunk of data using the first ECC.

### Example 9

The apparatus of example 8, the logic may receive the second chunk of data from a host computing device. The second chunk of data may be source encoded such that source data included in the second chunk of data has not been compressed enough to enable the combined storage size of the second chunk of encoded data and the open information to not exceed the given storage size.

### Example 10

The apparatus of example 8, the logic may receive a read request for the second chunk of data stored to the physical memory addresses. The logic may also decode the first ECC encoded second chunk of data. The logic, responsive to an unsuccessful correction of bit errors in the decoded second chunk of data using the first ECC, may also identify locations of the open bit lines for the physical memory addresses based on a Vpass read command to all bit lines for the physical memory address. The logic may also decode the first ECC encoded second chunk of data using the identified locations of open bit lines as erasures to successfully correct bit errors in the decoded second chunk of data using the first ECC.

### Example 11

The apparatus of example 1, the physical memory addresses may be arranged to store the chunk of data of a given storage size comprising a memory band. For these examples, the logic may receive the open information indicating locations of open bit lines for the physical memory addresses from a temporarily assigned storage for the memory band. The locations of open bit lines may be identified based on Vpass read command to write lines of the memory band.

### Example 12

The apparatus of example 1, the one or more memory devices includes non-volatile or volatile types of memory.

### Example 13

The apparatus of example 12, the volatile types of memory comprising DRAM.

### Example 14

The apparatus of example 12, the non-volatile types of memory may include 3-dimensional cross-point memory, memory that uses chalcogenide phase change material, flash memory, ferroelectric memory, SONOS memory, polymer memory, ferroelectric polymer memory, FeTRAM, FeRAM, ovonic memory, nanowire, electrically EEPROM, phase change memory, memristors or STT-MRAM.

### Example 15

The apparatus of example 14, the one or more memory devices and the controller may be included in a solid state drive coupled with a host computing device.

### Example 16

An example method may include receiving, at circuitry for a memory system, open information indicating locations of open bit lines for physical memory addresses of one or more memory devices maintained at the memory system. The physical memory addresses may be arranged to store a chunk of data of a given storage size. The method may also include receiving a first chunk of data for storage to the physical memory addresses. The method may also include determining whether the combined storage size of the first chunk of data and the open information exceeds the given storage size. The method may also include storing the first chunk of data with the open information to the physical memory addresses based on the combined storage size not exceeding the given storage size.

### Example 17

The method of example 16, determining whether the combined storage size of the first chunk of data and the open information exceeds the given storage size may include determining a storage size for the first chunk of data following encoding using a first ECC and determining a storage size for the open information following encoding with a second ECC.

### Example 18

The method of example 17 may include receiving the first chunk of data from a host computing device coupled with the memory system. The first chunk of data may have been source encoded such that source data included in the first chunk of data has been compressed enough to enable the first chunk of encoded data and the open information to have the combined storage size that does not exceed the given storage size.

### Example 19

The method of example 17, the first ECC and the second ECC may be a same ECC selected from one of an LDPC ECC, an RS ECC or a BCH ECC.

### Example 20

The method of example 17, the first ECC and the second ECC may be different. For these examples, the first ECC may be an LDPC ECC and the second ECC may be one of an RS ECC or a BCH ECC.

### Example 21

The method of example 17, storing the first chunk of data with the open information may include encoding the first chunk of data using the first ECC, encoding the open information using the second ECC and storing the first ECC encoded first chunk of data with the second ECC encoded open information to the physical memory addresses.

### Example 22

The method of example 21 may include receiving a read request for the first chunk of data stored to the physical memory addresses. The method may also include decoding the first ECC encoded first chunk of data. Responsive to unsuccessfully correcting bit errors in the decoded first chunk of data using the first ECC, the method may also include decoding the second ECC encoded open information to identify locations of open bits lines for the physical memory addresses. The method may also include indicating that the identified locations of open bit lines are erasures. The method may also include decoding the first ECC encoded first chunk of data using the identified locations of open bit lines as erasures. The method may also include successfully correcting bits errors bit errors in the decoded first chunk of data using the first ECC.

### Example 23

The method of example 17 may include receiving a second chunk of data for storage to the physical memory addresses. The method may also include determining that the combined storage size of the second chunk of data and the open information exceeds the given storage size. The method may also include encoding the chunk of data using the first ECC.

### Example 24

The method of example 23 may include receiving the second chunk of data from a host computing device coupled with the memory system. For these examples, the second chunk of data may have been source encoded such that source data included in the second chunk of data has not been compressed enough to enable the combined storage size of the second chunk of encoded data and the open information to not exceed the given storage size.

### Example 25

The method of example 23 may include receiving a read request for the second chunk of data stored to the physical memory addresses. The method may also include decoding the first ECC encoded second chunk of data. Responsive to unsuccessfully correcting bit errors in the decoded second chunk of data using the first ECC, the method may also include identifying locations of the open bit lines for the physical memory addresses based on a Vpass read command to all bit lines for the physical memory address. The method may also include indicating that the identified locations of open bit lines are erasures. The method may also include decoding the first ECC encoded second chunk of data using the identified locations of open bit lines as erasures. The method may also include successfully correcting bits errors bit errors in the decoded second chunk of data using the first ECC.

### Example 26

The method of example 16, the physical memory addresses may be arranged to store the chunk of data of a given storage size comprising a memory band. The method may also include receiving the open information indicating locations of open bit lines for the physical memory addresses from a temporarily assigned storage for the memory band. The locations of open bit lines may be identified based on a Vpass read command to write lines of the memory band.

### Example 27

The method of example 16, the memory system may include non-volatile or volatile types of memory.

### Example 28

The method of example 27, the volatile types of memory may include DRAM.

### Example 29

The method of example 27, the non-volatile types of memory may include 3-dimensional cross-point memory, memory that uses chalcogenide phase change material, flash memory, ferroelectric memory, SONOS memory, polymer memory, ferroelectric polymer memory, FeTRAM, FeRAM, ovonic memory, nanowire, electrically EEPROM, phase change memory, memristors or STT-MRAM.

### Example 30

An example at least one machine readable medium may include a plurality of instructions that in response to being executed by a system may cause the system to carry out a method according to any one of examples 16 to 29.

### Example 31

An apparatus may include means for performing the methods of any one of examples 16 to 29.

### Example 32

An example system may include a processor for a host computing device to execute one or more applications. The system may also include a memory system coupled with the host computing platform. For these examples, the memory system may include one or more memory devices and a controller that includes logic, at least a portion of which is implemented as hardware. The logic may receive open information indicating locations of open bit lines for physical memory addresses of the one or more memory devices. The physical memory addresses may be arranged to store a chunk of data of a given storage size. The logic may also receive a first chunk of data for storage to the physical memory addresses. The first chunk of data may be received from an application executed by the processor. The logic may also determine whether the combined storage size of the first chunk of data and the open information exceeds the given storage size. The logic may also cause the first chunk of data to be stored with the open information to the physical memory addresses based on the combined storage size not exceeding the given storage size.

### Example 33

The system of example 32, the logic to determine whether the combined storage size of the first chunk of data and the open information exceeds the given storage size may include the logic to determine a storage size for the first chunk of data following encoding using a first ECC and determine a storage size for the open information following encoding with a second ECC.

### Example 34

The system of example 33, the first chunk of data received from the application may have been source encoded such that source data included in the first chunk of data has been compressed by the application enough to enable the first chunk of encoded data and the open information to have the combined storage size that does not exceed the given storage size.

### Example 35

The system of example 33, the first ECC and the second ECC may be a same ECC selected from one of an LDPC ECC, an RS ECC or a BCH ECC.

### Example 36

The system of example 33, the first ECC and the second ECC may be different. For these examples, the first ECC may be an LDPC ECC and the second ECC may be one of an RS ECC or a BCH ECC.

### Example 37

The system of example 33, the logic to store the first chunk of data with the open information may include the logic to encode the first chunk of data using the first ECC, encode the open information using the second ECC and cause the first ECC encoded first chunk of data to be stored with the second ECC encoded open information to the physical memory addresses.

### Example 38

The system of example 37 may also include the logic to receive a read request for the first chunk of data stored to the physical memory addresses. The logic may also decode the first ECC encoded first chunk of data. Responsive to an unsuccessful correction of bit errors in the decoded first chunk of data using the first ECC, the logic may also decode the second ECC encoded open information to identify locations of open bits lines for the physical memory addresses. The logic may also decode the first ECC encoded first chunk of data using the identified locations of open bit lines as erasures to successfully correct bits errors in the decoded first chunk of data using the first ECC.

### Example 39

The system of example 33 may also include the logic to receive a second chunk of data for storage to the physical memory addresses. The second chunk of data may have been received from a second application executed by the processor. The logic may also determine that the combined storage size of the second chunk of data and the open information exceeds the given storage size. The logic may also encode the chunk of data using the first ECC.

### Example 40

The system of example 39, the second chunk of data may be received from the second application being source encoded such that source data included in the second chunk of data has not been compressed enough to enable the combined storage size of the second chunk of encoded data and the open information to not exceed the given storage size.

### Example 41

The system of example 39 may also include the logic to receive a read request for the second chunk of data stored to the physical memory addresses. The logic may also decode the first ECC encoded second chunk of data. Responsive to an unsuccessful correction of bit errors in the decoded second chunk of data using the first ECC, the logic may also identify locations of the open bit lines for the physical memory addresses based on a Vpass read command to all bit lines for the physical memory address. The logic may also decode the first ECC encoded second chunk of data using the identified locations of open bit lines as erasures to successfully correct bit errors in the decoded second chunk of data using the first ECC.

### Example 42

The system of example 32, the physical memory addresses arranged to store the chunk of data of a given storage size may include a memory band. For these examples, the logic may receive the open information indicating locations of open bit lines for the physical memory addresses from a temporarily assigned storage for the memory band. The locations of open bit lines may have been identified based on a Vpass read command to write lines of the memory band.

### Example 43

The system of example 32, the one or more memory devices may include non-volatile or volatile types of memory.

### Example 44

The system of example 43, the volatile types of memory may include DRAM.

### Example 45

The system of example 43, the non-volatile types of memory may include 3-dimensional cross-point memory, memory that uses chalcogenide phase change material, flash memory, ferroelectric memory, SONOS memory, polymer memory, ferroelectric polymer memory, FeTRAM, FeRAM, ovonic memory, nanowire, electrically EEPROM, phase change memory, memristors or STT-MRAM.

### Example 46

The system of example 45, the storage device may be a solid state drive.

### Example 47

The system of example 32 may also include one or more of:

A network interface communicatively coupled to the at least one processor; a display communicatively coupled to the at least one processor; or a battery communicatively coupled to the at least one processor.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. An apparatus comprising:
one or more memory devices; and
a controller that includes logic, at least a portion of which comprises hardware, the logic to:
receive open information indicating locations of open bit lines for physical memory addresses of the one or more memory devices, the physical memory addresses arranged to store a chunk of data of a given storage size;
receive a first chunk of data for storage to the physical memory addresses;
determine whether the combined storage size of the first chunk of data and the open information exceeds the given storage size; and
cause the first chunk of data to be stored with the open information to the physical memory addresses based on the combined storage size not exceeding the given storage size.

2. The apparatus of claim 1, the logic to determine whether the combined storage size of the first chunk of data and the open information exceeds the given storage size comprises the logic to:
determine a storage size for the first chunk of data following encoding using a first error correction code (ECC); and
determine a storage size for the open information following encoding with a second ECC.

3. The apparatus of claim 2, the logic to receive the first chunk of data from a host computing device, the first chunk of data being source encoded such that source data included in the first chunk of data has been compressed enough to enable the first chunk of encoded data and the open information to have the combined storage size that does not exceed the given storage size.

4. The apparatus of claim 2, comprising the first ECC and the second ECC are a same ECC selected from one of a low-density parity-check (LDPC) ECC, a Reed-Solomon (RS) ECC or a Bose, Chaudhuri, and Hocquenghem (BCH) ECC.

5. The apparatus of claim 2, comprising the first ECC and the second ECC are different, the first ECC is an LDPC ECC and the second ECC is one of an RS ECC or a BCH ECC.

6. The apparatus of claim 2, the logic to store the first chunk of data with the open information comprises the logic to:
encode the first chunk of data using the first ECC;
encode the open information using the second ECC; and
cause the first ECC encoded first chunk of data to be stored with the second ECC encoded open information to the physical memory addresses.

7. The apparatus of claim 6, comprising the logic to:
receive a read request for the first chunk of data stored to the physical memory addresses;
decode the first ECC encoded first chunk of data; and
responsive to an unsuccessful correction of bit errors in the decoded first chunk of data using the first ECC, the logic to:
decode the second ECC encoded open information to identify locations of open bits lines for the physical memory addresses; and
decode the first ECC encoded first chunk of data using the identified locations of open bit lines as erasures to successfully correct bits errors in the decoded first chunk of data using the first ECC.

8. The apparatus of claim 2, comprising the logic to:
receive a second chunk of data for storage to the physical memory addresses;
determine that the combined storage size of the second chunk of data and the open information exceeds the given storage size; and
encode the chunk of data using the first ECC.

9. The apparatus of claim 8, the logic to receive the second chunk of data from a host computing device, the second chunk of data source encoded such that source data included in the second chunk of data has not been compressed enough to enable the combined storage size of the second chunk of encoded data and the open information to not exceed the given storage size.

10. The apparatus of claim 8, comprising the logic to:
receive a read request for the second chunk of data stored to the physical memory addresses;
decode the first ECC encoded second chunk of data; and
responsive to an unsuccessful correction of bit errors in the decoded second chunk of data using the first ECC, the logic to:
identify locations of the open bit lines for the physical memory addresses based on a Vpass read command to all bit lines for the physical memory address; and
decode the first ECC encoded second chunk of data using the identified locations of open bit lines as erasures to successfully correct bit errors in the decoded second chunk of data using the first ECC.

11. The apparatus of claim 1, the physical memory addresses arranged to store the chunk of data of a given storage size comprising a memory band, the logic to receive the open information indicating locations of open bit lines for the physical memory addresses from a temporarily assigned storage for the memory band, the locations of open bit lines identified based on a pass voltage (Vpass) read command to write lines of the memory band.

12. The apparatus of claim 1, the one or more memory devices includes non-volatile or volatile types of memory.

13. The apparatus of claim 12, the volatile types of memory comprising dynamic random access memory (DRAM).

14. The apparatus of claim 12, the non-volatile types of memory comprising 3-dimensional cross-point memory, memory that uses chalcogenide phase change material, flash memory, ferroelectric memory, silicon-oxide-nitride-oxide-silicon (SONOS) memory, polymer memory, ferroelectric polymer memory, ferroelectric transistor random access memory (FeTRAM or FeRAM), ovonic memory, nanowire, electrically erasable programmable read-only memory (EEPROM), phase change memory, memristors or spin transfer torque—magnetoresistive random access memory (STT-MRAM).

15. The apparatus of claim 14, comprising the one or more memory devices and the controller included in a solid state drive coupled with a host computing device.

16. A method comprising:
receiving, at circuitry for a memory system, open information indicating locations of open bit lines for physical memory addresses of one or more memory devices maintained at the memory system, the physical memory addresses arranged to store a chunk of data of a given storage size;
receiving a first chunk of data for storage to the physical memory addresses;
determining whether the combined storage size of the first chunk of data and the open information exceeds the given storage size; and
storing the first chunk of data with the open information to the physical memory addresses based on the combined storage size not exceeding the given storage size.

17. The method of claim 16, determining whether the combined storage size of the first chunk of data and the open information exceeds the given storage size comprising:
determining a storage size for the first chunk of data following encoding using a first error correction code (ECC); and
determining a storage size for the open information following encoding with a second ECC.

18. The method of claim 17, receiving the first chunk of data from a host computing device coupled with the memory system, the first chunk of data being source encoded such that source data included in the first chunk of data has been compressed enough to enable the first chunk of encoded data and the open information to have the combined storage size that does not exceed the given storage size.

19. The method of claim 17, storing the first chunk of data with the open information comprising:
encoding the first chunk of data using the first ECC;
encoding the open information using the second ECC; and
storing the first ECC encoded first chunk of data with the second ECC encoded open information to the physical memory addresses.

20. The method of claim 19, comprising:
receiving a read request for the first chunk of data stored to the physical memory addresses;
decoding the first ECC encoded first chunk of data; and
responsive to unsuccessfully correcting bit errors in the decoded first chunk of data using the first ECC:
decoding the second ECC encoded open information to identify locations of open bits lines for the physical memory addresses;
indicating that the identified locations of open bit lines are erasures;
decoding the first ECC encoded first chunk of data using the identified locations of open bit lines as erasures; and
successfully correcting bits errors bit errors in the decoded first chunk of data using the first ECC.

21. A system comprising:
at least one processor for a host computing device to execute one or more applications;
a memory system coupled with the host computing platform, the memory system including:
one or more memory devices; and
a controller that includes logic, at least a portion of which is implemented as hardware, the logic to:
receive open information indicating locations of open bit lines for physical memory addresses of the one or more memory devices, the physical memory addresses arranged to store a chunk of data of a given storage size;
receive a first chunk of data for storage to the physical memory addresses, the first chunk of data received from an application executed by the processor;
determine whether the combined storage size of the first chunk of data and the open information exceeds the given storage size; and
cause the first chunk of data to be stored with the open information to the physical memory addresses based on the combined storage size not exceeding the given storage size.

22. The system of claim 21, the logic to determine whether the combined storage size of the first chunk of data and the open information exceeds the given storage size comprises the logic to:
determine a storage size for the first chunk of data following encoding using a first error correction code (ECC); and
determine a storage size for the open information following encoding with a second ECC.

23. The system of claim 22, the logic to store the first chunk of data with the open information comprises the logic to:
encode the first chunk of data using the first ECC;
encode the open information using the second ECC; and
cause the first ECC encoded first chunk of data to be stored with the second ECC encoded open information to the physical memory addresses.

24. The system of claim 23, comprising the logic to:
receive a read request for the first chunk of data stored to the physical memory addresses;
decode the first ECC encoded first chunk of data; and
responsive to an unsuccessful correction of bit errors in the decoded first chunk of data using the first ECC, the logic to:
decode the second ECC encoded open information to identify locations of open bits lines for the physical memory addresses; and
decode the first ECC encoded first chunk of data using the identified locations of open bit lines as erasures to successfully correct bits errors in the decoded first chunk of data using the first ECC.

25. The system of claim 21, the physical memory addresses arranged to store the chunk of data of a given storage size comprising a memory band, the logic to receive the open information indicating locations of open bit lines for the physical memory addresses from a temporarily assigned storage for the memory band, the locations of open bit lines identified based on a pass voltage (Vpass) read command to write lines of the memory band.

26. The system of claim 21, further comprising one or more of:
a network interface communicatively coupled to the at least one processor;
a display communicatively coupled to the at least one processor; or
a battery communicatively coupled to the at least one processor.
